(19) United States
(12) Patent Application Publication
(10) Pub. No.: US 2024/0380383 A1
(43) Pub. Date: Nov. 14, 2024

(54) Surface Acoustic Wave Resonators With Interdigital Transducers Of Differing Duty Factor and Pitch

(71) Applicant: Qorvo US, Inc., Greensboro, NC (US)

(72) Inventors: Pedram Loghmannia, Greensboro, NC (US); Jason McGann, Greensboro, NC (US); Marc Solal, Greensboro, NC (US)

(21) Appl. No.: 18/640,474

(22) Filed: Apr. 19, 2024

Related U.S. Application Data
(60) Provisional application No. 63/501,869, filed on May 12, 2023.

(51) Int. Cl. H03H 9/25; H03H 9/145; H03H 9/72

(52) U.S. Cl. CPC H03H 9/25; H03H 9/14541; H03H 9/725

(57) ABSTRACT

A surface acoustic wave (SAW) resonator device includes a piezoelectric layer and a first subset of electrodes positioned on the piezoelectric layer. The first subset of electrodes corresponds to a first width, a first pitch, a fundamental resonant frequency, and a first higher order resonant frequency. The SAW resonator device also includes a second subset of electrodes positioned on the piezoelectric layer. The second subset of electrodes corresponds to a second width and a second pitch different from the first width and first pitch. The second subset of electrodes also corresponds to the same fundamental resonance frequency and a second higher order resonant frequency different from the first higher order resonant frequency.

### TECHNICAL FIELD

This application claims priority to U.S. Provisional Patent Application No. 63/501,869 filed May 12, 2023, which is incorporated by reference herein its entirety.

### TECHNICAL FIELD

The present disclosure relates generally to multiplexer circuits. In particular, an interdigital transducer of a surface acoustic wave resonator of a multiplexer includes multiple sections of varying widths and pitches corresponding to a uniform fundamental resonant frequency and varying second order resonant frequencies.

### BACKGROUND

A surface acoustic wave (SAW) resonator is a device that uses the mechanical vibrations of a piezoelectric material to filter and process electrical signals. SAW resonators are commonly used in electronic communication devices. SAW resonators are small, low-cost, and highly reliable resonators used for electronic filters which makes them ideal for use in compact electronic devices such as cellular phones.

Ideally, SAW resonators have a single resonance frequency, known as the fundamental resonance frequency, and no higher order resonance frequencies, referred to herein as spurious content. Unfortunately, depending on the technology, several acoustic modes are excited in the resonator in addition to the fundamental resonance frequency. These additional modes often result in the presence of spurious content. In that regard, the resonator has high admittance not only at the fundamental resonance frequency but also at other frequencies. In addition to transverse modes which are at frequencies close to the fundamental resonance frequency, modes further from the fundamental resonance frequency are present. For example, a plate mode can be present for devices using a silicon oxide overcoat layer. The frequency of this plate mode is often about 30% above the fundamental resonance frequency. For resonators using a layered substrate, extra modes are also present typically above the fundamental mode. When the resonator is used in a filter, these extra modes cause the input admittance of the filter to have a large real part at the frequencies corresponding to spurious modes. In modern RF communication systems, it is now very common to use carrier aggregation, meaning that several bands are used at the same time. In this case, several filters or duplexers are connected to a single antenna node. If the spurious content of one filter is within the passband frequencies of a second filter, this spurious content will introduce extra losses to the second filter. It is very common for spurious content have a sharp and narrow band frequency response, meaning that the spurious content of the first filter may cause a very large ripple or notch in the passband of the second filter, causing signal degradation.

Some techniques have been utilized in an attempt to overcome this issue. As an example, external matching components may be added to a multiplexer circuit to suppress spurious content. However, this technique significantly increases cost and requires more space due to the extra components used. In addition, matching components may introduce their own extra loss to other parts of a multiplexer circuit. Another solution includes altering the stack to push the spurious content out of the desired bands. However, altering stacks often degrades critical resonator performances like temperature coefficient of frequency (TCF), coupling factor, and Q-factor. Also, altering stacks slows the design cycle because the new stack needs to be fully characterized before initiating the filter design. Therefore, there is a need for further techniques to reduce degradation of the signals through a filter.

### SUMMARY

Embodiments of the present disclosure include devices, systems, and methods to improve out of band loading effect of SAW resonators used in transmit-receive multiplexers via frequency modulation of spurious modes. Aspects of the disclosure advantageously provide SAW resonator devices with decreased amplitude of spurious content from higher order modes, such as plate modes, resulting in increased signal quality.

In an exemplary aspect, a surface acoustic wave (SAW) resonator device is provided. The SAW device includes a piezoelectric layer; a first subset of electrodes positioned on the piezoelectric layer, the first subset of electrodes corresponding to: a first width; a first pitch; a fundamental resonant frequency; and a first higher order resonant frequency; and a second subset of electrodes positioned on the piezoelectric layer, the second subset of electrodes corresponding to: a second width; a second pitch; the fundamental resonance frequency; and a second higher order resonant frequency different from the first higher order resonant frequency.

In some aspects, the first width is greater than the second width and wherein the first pitch is less than the second pitch. In some aspects, each electrode of the first and second subsets of electrodes comprises an upper electrode layer and a lower electrode layer. In some aspects, the first higher order resonant frequency and the second higher order resonant frequency corresponding to a peak that is lower in amplitude than a corresponding number of electrodes of uniform width and uniform pitch. In some aspects, the SAW resonator device further comprises a third subset of electrodes positioned on the piezoelectric layer, the third subset of electrodes corresponding to: a third width; a third pitch; the fundamental resonance frequency; and a third higher order resonant frequency different from the first higher order resonant frequency and the second higher order resonant frequency. In some aspects, either of the first higher order resonant frequency or the second higher order resonant frequency corresponds to a plate mode. In some aspects, the electrode periods and the electrode widths vary along the resonator; and a larger electrode width correspond to a smaller pitch. In some aspects, the electrodes of the first and second subsets of electrodes are embedded in a dielectric material. In some aspects, the dielectric material is silicon oxide. In some aspects, the dielectric material thickness is greater than about 30% of the period. In some aspects, the piezoelectric material includes lithium niobate with an orientation between about Y+115 deg. and about Y+130 deg. In some aspects, the piezoelectric layer is lithium tantalate or lithium niobate.

In an exemplary aspect, a multiplexer system is provided. The multiplexer system includes multiple receive and transmit ports; an antenna port; and a plurality of filters in communication with the receive port(s), the transmit port(s), and the antenna port, wherein a first filter of the plurality of filters includes a surface acoustic wave (SAW) resonator comprising an interdigital transducer including a plurality of electrodes, wherein the interdigital transducer comprises: a first section with a first electrode width and a first electrode pitch corresponding to a fundamental resonant frequency and a first higher order resonant frequency; and a second section with a second electrode width and a second electrode pitch corresponding to the fundamental resonance frequency and a second higher order resonant frequency different from the first higher order resonant frequency.

In some aspects, the SAW resonator is directly coupled to the antenna port. In some aspects, each electrode of the plurality of electrodes comprises a first region of a first width and a first pitch and a second region of a second width and a second pitch. In some aspects, a first subset of electrodes corresponds to a first busbar of the interdigital transducer and wherein the first region of the first subset of electrodes corresponds to a proximal region and the second region of the first subset of electrodes corresponds to a distal region; and a second subset of electrodes corresponds to a second busbar of the interdigital transducer and wherein the first region of a second subset of electrodes corresponds to a distal region and the second region of the second subset of electrodes corresponds to a proximal region. In some aspects, the width and pitch of each electrodes of the plurality of electrodes is continuously varied along the length of each electrode between the first region and the second region. In some aspects, the first section includes a first subset of the plurality of electrodes and the second section includes a second subset of the plurality of electrodes. In some aspects, the first subset of the plurality of electrodes correspond to the first electrode width and the first electrode pitch. In some aspects, the second subset of the plurality of electrodes correspond to the second electrode width and the second electrode pitch. In some aspects, the interdigital transducer comprises at least five sections, each section corresponding to a different electrode width and a different electrode pitch. In some aspects, the filters of the plurality of filters are arranged in series and parallel and wherein a subset of the filters of the plurality of filters include varying electrode widths and varying electrode pitches. In some aspects, the subset includes the first filter and wherein the first filter is positioned closest to the antenna.

In an exemplary aspect, a method is provided. The method includes: determining a width and a pitch of a plurality of electrodes of a surface acoustic wave (SAW) device, such that the width and the pitch of the plurality of electrodes correspond to a fundamental resonant frequency and a first spurious resonant frequency of a first amplitude; and modifying the width and the pitch of the a subset of the plurality of electrodes of the SAW device, such that the fundamental resonant frequency of the subset of the plurality of electrodes of the SAW device remains unchanged and the subset of the plurality of electrodes of the SAW device corresponds to a second spurious resonant frequency different from the first spurious resonant frequency, wherein the first spurious resonant frequency and the second spurious resonant frequency form a combined spurious resonance of a second amplitude less than the first amplitude.

In some aspects, modifying the width of the subset of electrodes of the SAW device includes increasing the width of the subset of electrodes. In some aspects, modifying the pitch of the subset of electrodes of the SAW device includes decreasing the pitch of the subset of electrodes.

In an exemplary aspect, an interdigital transducer (IDT) is provided. The IDT includes: a plurality of sections, wherein each section of plurality of sections corresponds to: a different period; and a different electrode width; wherein the period and electrode of the plurality of sections is varied according to an inverse relationship such that sections of increased electrode width correspond to decreased period.

Additional aspects, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1A is a perspective view of a representative low-loss resonator technology surface acoustic wave (LRT-SAW) device.

FIG. 1B is a perspective view of a representative temperature compensated surface acoustic wave (TC-SAW) device.

FIG. 2 is a diagrammatic view of multiplexer circuit.

FIG. 3 is a diagrammatic view of a duplexer circuit.

FIG. 4 is a graphical representation of return loss of an antenna port of a duplexer.

FIG. 5 is a graphical representation of a transfer function of one of the filters in the multiplexer.

FIG. 6 is a cross-sectional side view of electrodes of a SAW device.

FIG. 7 is a graphical representation of conductance of a SAW resonator.

FIG. 8 is a cross-sectional side view of electrodes of a SAW device.

FIG. 9 is a graphical representation of conductance of SAW resonators.

FIG. 10 is a cross-sectional side view of electrodes of a SAW device.

FIG. 11 is a graphical representation of conductance of SAW resonators.

FIG. 12 is a cross-sectional side view of electrodes of a SAW device, according to aspects of the present disclosure.

FIG. 13 is a diagrammatic view of SAW resonators, according to aspects of the present disclosure.

FIG. 14 is a graphical representation of conductance of SAW resonators, according to aspects of the present disclosure.

FIG. 15 is a graphical representation of return loss of an antenna port of a duplexer, according to aspects of the present disclosure.

FIG. 16 is a graphical representation of a transfer function of one of the filters in the multiplexer, according to aspects of the present disclosure.

FIG. 17 is a top view of interdigital transducers of a SAW resonator, according to aspects of the present disclosure.

FIG. 18 is a top view of interdigital transducers of a SAW resonator, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

An interdigital transducer has a fundamental resonance frequency, and in some cases, spurious modes. In particular, when the transducer electrodes are embedded in silicon oxide to reduce its temperature sensitivity, a plate mode may exist. If the transducer is on a layered substrate other spurious modes may exist too. The fundamental resonance frequency may be the desired frequency of the transducer and may correspond to a pass band of a designed filter. The plate mode is a higher order mode or resonance frequency, sometimes referred to as spurious content, that is unwanted and can interfere with other resonators or filters in a multiplexer or other circuit leading to signal degradation.

The fundamental resonance frequency of an interdigital transducer depends, at least in part, on the duty factor and pitch of the interdigital transducer. The pitch of an interdigital transducer is the distance an electrode is positioned from a neighboring electrode. The duty factor of an electrode may correspond to the ratio of the width of the electrode and the pitch. For example, the resonance frequency of an interdigital transducer electrode may be determined by f=v/2p, where f corresponds to the resonance frequency, v corresponds to a velocity, and p corresponds to the pitch. In some aspects, the velocity v may depend on the duty factor. Thus, as the duty factor of an electrode is increased (e.g., by increasing the width of the electrode), the fundamental resonance frequency of the electrode may decrease while the plate mode remains the same or similar frequency. As the pitch is decreased, the fundamental frequency and plate mode of the interdigital transducer is increased. By varying the width and pitch of interdigital transducer electrodes within a SAW device, multiple interdigital transducer electrodes may be configured to correspond to the same fundamental resonance frequency but will generate plate modes or spurious modes at varying frequency. As a result, plate modes or other spurious modes may be moved outside of pass band frequencies of the other filters in the multiplexer and/or suppressed in amplitude thus improving the signal quality of the other filters in the multiplexer circuit.

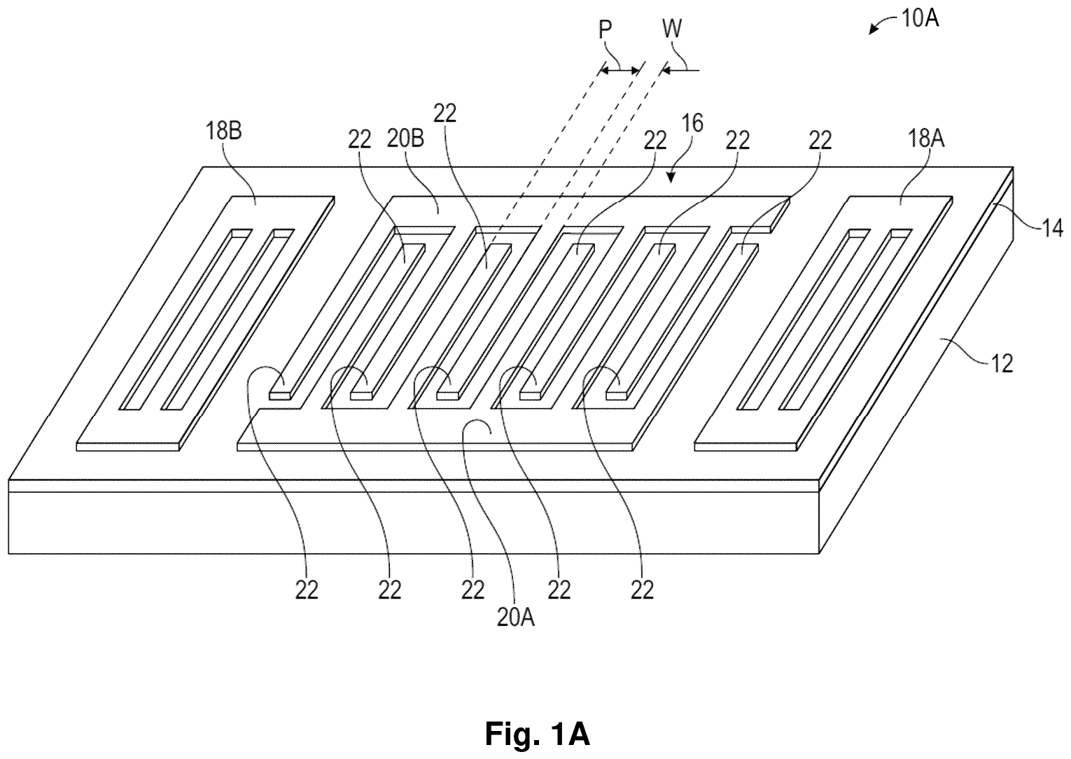

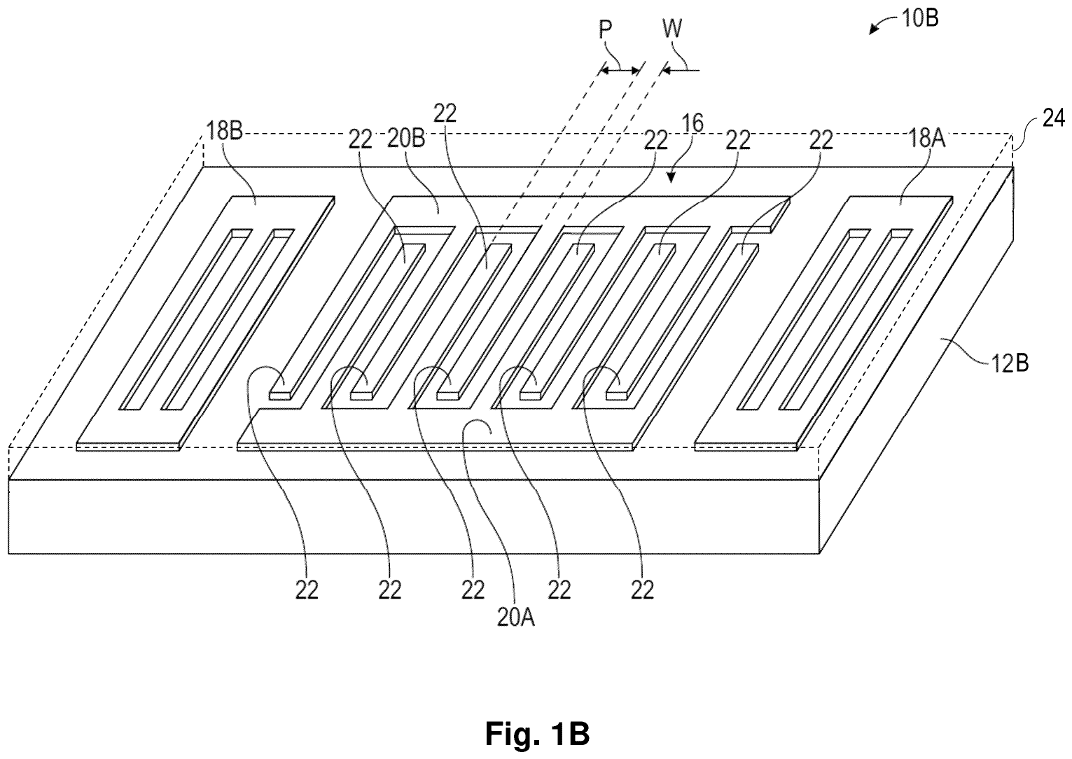

FIG. 1A is a perspective view of a representative low-loss resonator technology surface acoustic wave (LRT-SAW) device 10A. The LRT-SAW device 10A includes a substrate 12, a piezoelectric layer 14 on the substrate 12, an interdigital transducer (IDT) 16 including multiple electrodes 22 on a surface of the piezoelectric layer 14 opposite the substrate 12, a first reflector structure 18A on the surface of the piezoelectric layer 14 adjacent to the interdigital transducer 16, and a second reflector structure 18B on the surface of the piezoelectric layer 14 adjacent to the interdigital transducer 16 opposite the first reflector structure 18A. In certain aspects, the substrate 12 may be referred to as a carrier substrate and the LRT-SAW device 10A may be referred to as a guided SAW device. The layered substrate shown in FIG. 1A may comprise multiple layers. The piezoelectric layer 14 may also be referred to as a piezoelectric film and may be constructed of lithium tantalate or lithium niobate, or any other suitable material. The piezoelectric layer 14 may be bonded on the substrate 12, which may be referred to as a carrier substrate. It is understood that more than one film may be present, for example a silicon oxide film may be between the piezoelectric layer 14 and the carrier substrate 12.

The interdigital transducer 16 includes a first busbar 20A and a second busbar 20B, each of which may be connected to multiple electrodes 22 that are interleaved with one another as shown. The electrodes 22 may also be referred to as comb electrodes. A lateral distance between adjacent electrodes 22 connected to the first busbar 20A and the second busbar 20B defines a pitch P between adjacent electrodes 22. The pitch P may at least partially define a resonant frequency of the corresponding electrodes 22. In that regard, in aspects in which the pitch P between electrodes 22 is uniform, all electrodes 22 may be configured to correspond to the same resonant frequency. This resonant frequency may be the resonant frequency of the LRT-SAW device 10A. A resonant frequency may be a frequency such that the mechanical waves excited between all the gaps between the electrodes are in phase. Resonant frequency can be adjusted by changing the velocity and/or pitch. An electrode 22 width W together with the pitch P may define a metallization ratio, or duty factor, of IDT 16. Pitch and duty factor can be the same or different for different electrodes 22 of the IDT 16.

In operation, an alternating electrical input signal provided at the first busbar 20A is transduced into a mechanical signal in the piezoelectric layer 14, resulting in one or more acoustic waves therein. In the case of the SAW device 10, the resulting acoustic waves are predominately surface acoustic waves. As discussed above, due to the pitch P and the metallization ratio of the IDT 16, the characteristics of the material of the piezoelectric layer 14, and other factors, the magnitude of the acoustic waves transduced in the piezoelectric layer 14 are dependent on the frequency of the alternating electrical input signal. This frequency dependence is often described in terms of changes in the impedance and/or a phase shift between the first busbar 20A and the second busbar 20B with respect to the frequency of the alternating electrical input signal. An alternating electrical potential between the two busbars 20A and 20B creates an electrical field in the piezoelectric material which generates acoustic waves. The acoustic waves travel at the surface and eventually are transferred back into an electrical signal between the busbars 20A and 20B. The first reflector structure 18A and the second reflector structure 18B reflect the acoustic waves in the piezoelectric layer 14 back towards the IDT 16 to confine the acoustic waves in the area surrounding the IDT 16.

The substrate 12 may comprise various materials including glass, sapphire, quartz, silicon (Si), silicon carbide (SiC), or gallium arsenide (GaAs) among others, with Si being a common choice. The piezoelectric layer 14 may be formed of any suitable piezoelectric material(s). In certain embodiments described herein, the piezoelectric layer 14 is formed of lithium tantalate (LT), or lithium niobate (LiNbO₃), but is not limited thereto. In certain embodiments, the piezoelectric layer 14 is thick enough or rigid enough to function as a piezoelectric substrate. Accordingly, the substrate 12 in FIG. 1 may be omitted. Those skilled in the art will appreciate that the principles of the present disclosure may apply to other materials for the substrate 12 and the piezoelectric layer 14. The IDT 16, the first reflector structure 18A, and the second reflector structure 18B may comprise one or more of aluminum (Al), copper (Cu), titanium (Ti), platinum (Pt), tungsten (W), molybdenum (Mo) and alloys thereof in either single or multiple layer arrangements. While not shown to avoid obscuring the drawings, additional passivation layers, frequency trimming layers, or any other layers may be provided over all or a portion of the exposed surface of the piezoelectric layer 14, the IDT 16, the first reflector structure 18A, and the second reflector structure 18B. Such additional passivation layers may be provided for temperature compensation purposes and/or improved thermal conductivity, among other reasons. Further, one or more layers (such as silicon oxide) may be provided between the substrate 12 and the piezoelectric layer 14 in various embodiments. In some aspects, the thickness of the piezoelectric layer (e.g., layer 14) may be less than the acoustic wavelength. In aspects in which the piezoelectric layer 14 is formed of lithium niobate, the orientation of the piezoelectric layer 14 may be between Y+11 and Y+135. In other aspects in which the piezoelectric layer 14 is formed of lithium niobate, the orientation of the piezoelectric layer 14 may be between Y and Y+50. In aspects in which the piezoelectric layer 14 is formed of lithium tantalate, the orientation of the piezoelectric layer 14 may be between Y and Y+50. The electrodes of the SAW device may be formed of any suitable material, including platinum, rhodium, palladium, iridium, conductive ceramics, or any other suitable material. In some embodiments, the electrodes of the SAW device include the same materials as the reflectors, such as Al, Cu, Pt, W, Ti, Mo, or a combination thereof. In various embodiments, an electrode has a single layer or multiple layers.

FIG. 1B is a perspective view of a representative temperature compensated surface acoustic wave (TC-SAW) device 10B. In some aspects, the TC-SAW device 10B may be substantially similar to the LRT-SAW device 10A of FIG. 1A. In some aspects, the IDT 16 may be positioned on a substrate 12B constructed of lithium niobate or lithium tantalate. Also, to reduce the temperature sensitivity of the device, the IDT 16 may be embedded in a dielectric film 24. The dielectric film 24 may be constructed of silicon oxide. In the case of the TC-SAW device 10B, plate modes resonating in the silicon oxide film 24 may exist at a frequency roughly 30% above the resonant frequency. Depending on the substrate and the films used (often called the stack), various spurious modes may also exist, linked for example to resonance in one of several of the films.

In some aspects, the dielectric film 24 may additionally be referred to as a dielectric material overcoat. In some aspects, the dielectric film 24 may be doped silicon oxide, for example, doped with fluorine.

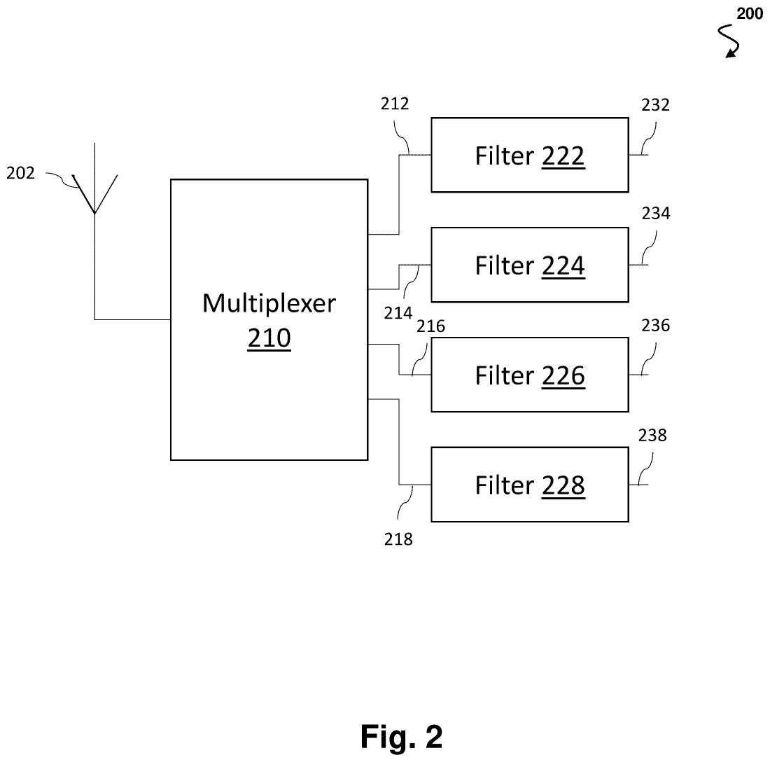

FIG. 2 is a diagrammatic view of multiplexer circuit 200. As shown in FIG. 2, the multiplexer circuit 200 connected to an antenna 202 and includes a multiplexer 210, filters 222, 224, 226, and 228. The circuit additionally includes leads 212, 214, 216, and 218, as well as leads (ports) 232, 234, 236, and 238.

The multiplexer circuit 200 shown in FIG. 2 may be a device that enables the transmission of multiple signals over a single communication channel. For example, each of the leads (ports) 232, 234, 236, and 238 may be configured to carry different signals at different frequencies. For example, any of the leads 232, 234, 236, and 238 may carry signals to be transmitted and/or received by the antenna 202. In the example shown, the antenna 202 may receive a communication channel corresponding to four different signals, each corresponding to the lines 232, 234, 236, and 238. In that regard, a signal intended for line 232 may be configured by the entity transmitting the signal within the pass band of the filter 222. Similarly, a signal intended for line 234 may be configured within the pass band of the filter 224, a signal intended for line 236 may be configured within the pass band of the filter 226, and a signal intended for line 238 may be configured within the pass band of the filter 228.

In some aspects, each of the filters 222, 224, 226, and 228 may affect the performance of each other. For example, while the bands of the filters 222, 224, 226, and 228 are designed to be separated from one another along the frequency spectrum, the frequency of spurious content from each of the filters 222, 224, 226, and 228 may be within the bands of other filters which causes interference.

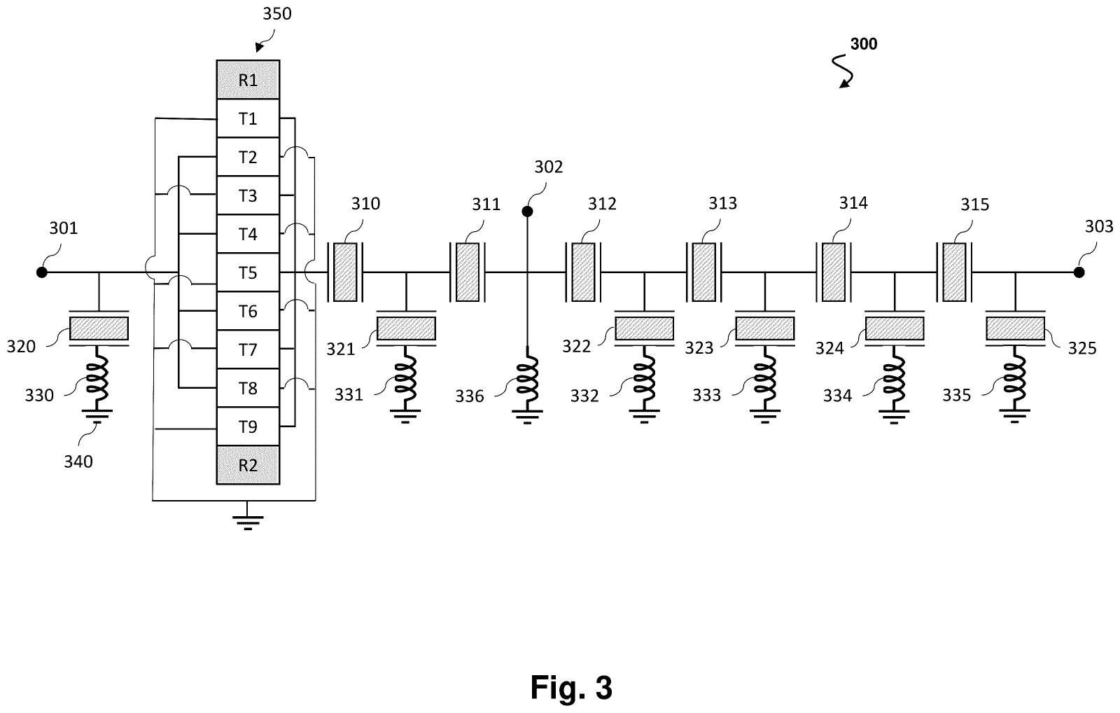

FIG. 3 is a diagrammatic view of a duplexer circuit 300. In some aspects, FIG. 3 may illustrate a duplexer topology for a band n74b duplexer. As shown in FIG. 3, the duplexer circuit 300 includes an antenna port 302, a receive port 301, and a transmit port 303. The duplexer circuit 300 may include multiple resonators and inductors. Specifically, a signal path from the antenna 302 to the receive port 301 includes a resonator 311, a resonator 321, an inductor 331 leading to ground 340, a resonator 310, a SAW coupled resonator 350, a resonator 320, and an inductor 330 to ground 340. The signal path from the antenna 302 to the transmit port 303 may include a resonator 312, a resonator 322, an inductor 332 to ground 340, a resonator 313, a resonator 323, an inductor 333 to ground 340, a resonator 314, a resonator 324, an inductor 334 to ground 340, a resonator 315, a resonator 325, and an inductor 335 to ground 340. The antenna 302 may also be indirect electrical communication with an inductor 336 to ground 340 as shown. Any of the resonator 320, 310, 321, 311, 312, 322, 313, 323, 314, 324, 315, and 325 may be any suitable type of resonator. In some aspects, any of the resonator 320, 310, 321, 311, 312, 322, 313, 323, 314, 324, 315, and 325 may be SAW resonators. In some aspects, the resonators 320, 310, 321, 311, and the coupled resonator 350 corresponding to the receive port 301 may be configured such that as a group, they form a pass band allowing signals intended to be received at the receive port 301. Similarly, the resonator 312, 322, 313, 323, 314, 324, 315, and 325 corresponding to the transmit port 303 may be configured such that, as a group, they form a pass band allowing signals intended to be transmitted by the antenna 302 from the transmit port 303. In that regard, the resonator of the receive port 301 may be configured to block content from the transmit port 303 and the filters of the transmit port 303 may be configured to block content from the antenna 302 intended for the receive port 301.

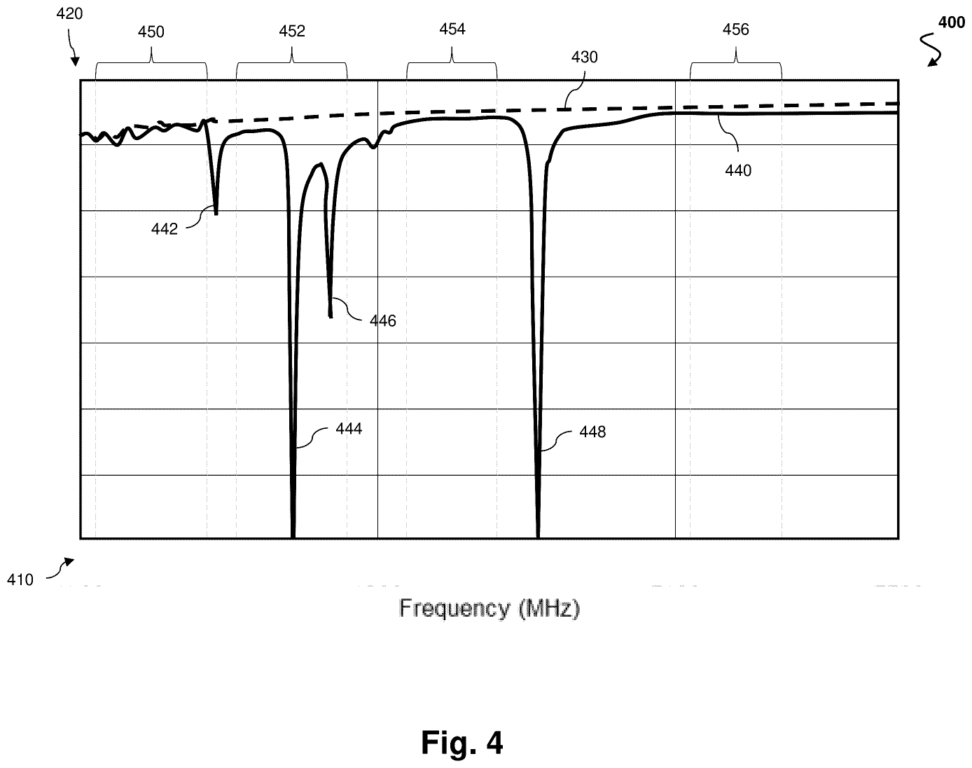

FIG. 4 is a graphical representation of return loss simulated from the antenna port 302 of the duplexer 300. In some aspects, the graphical representation may be a plot 400 including an x-axis 410 corresponding to frequency in MHz and a y-axis 420 corresponding to a return loss in dB or any other suitable unit.

The plot 400 includes an ideal return loss 430 of the duplexer 300. For example, this ideal return loss 430 may be the ideal performance of the duplexer 300 if each of the resonator of the duplexer 300 do not have any spurious content. The return loss 440 may be a simulated or actual return loss of the duplexer 300 which include spurious modes in the various resonators. It is important to note that since resonators 311 and 312 are directly connected to the antenna port, the return loss spurious seen on this port are mostly related to the spurious modes in these resonators.

As shown in FIG. 4, the frequency spectrum of plot 400 includes several bands, including bands 450, 452, 454, and 456. In the example shown, the bands 450, 452, 454, and 456 may correspond to pass bands from different filters within a multiplexer. As a non-limiting example, referring to FIG. 2, the band 450 may correspond to a pass band of filter 222, the band 452 may correspond to a pass band of filter 224, the band 454 may correspond to a pass band of filter 226, and the band 456 may correspond to a pass band of filter 228. These filters and corresponding bands may be used by receive or transmit ports of the antenna or for any other signal communication.

In some aspects, the pass band of the duplexer 300 (referring to FIG. 3) may be centered around 1500 MHZ. In that regard, the pass band of the duplexer 300 of FIG. 3 may not be shown along the frequency spectrum of the plot 400. However, the return loss 440 of plot 400 may include several notches or spikes caused by higher order spurious resonant frequencies of various resonators of the duplexer 300. These spurious resonant frequencies may be caused by plate modes of SAW resonators within filters, such as any of the filters shown and described with reference to FIG. 3. These spurious resonant frequencies, while not affecting the passband of the duplexer 300, may negatively affect the filters having passbands shown in FIG. 4.

In particular, a notch 442 is observed between bands 450 and 452. In some aspects, this notch 442 may be a plate mode of the resonator 322 of the duplexer 300. A notch 444 may be within the band 452 and may be a plate mode of the resonator 312 of the duplexer 300. Similarly, a notch 446 may be within the band 452 and may be a plate mode of the resonator 321 of the duplexer 300. A notch 448 may be between the bands 454 and 456 and may be a plate mode of the resonator 311 of the duplexer 300. These notches negatively impact the performance of the multiplexed filters corresponding to the bands shown in plot 400. In particular, the notches 444 and 446 within the band 452 may negatively affect the passband performance of a filters multiplexed and associated with the band 452 causing degradation of the signal transmitted or received within this pass band.

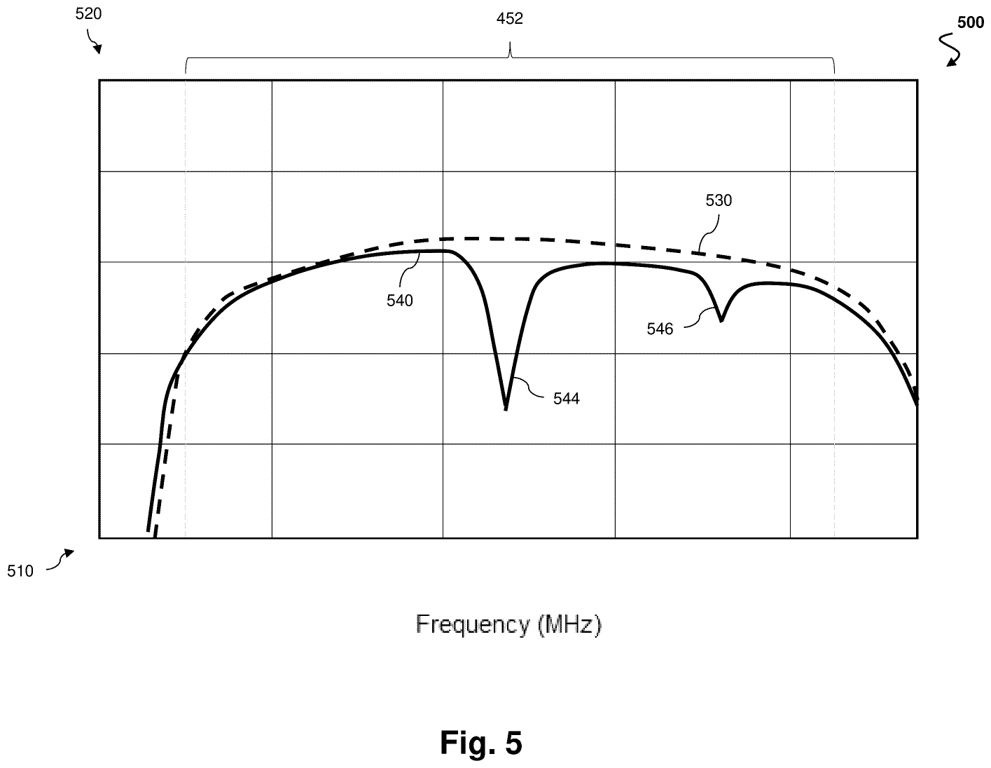

FIG. 5 is a graphical representation of a transmission transfer function of a filter in a multiplexer. FIG. 5 includes a plot 500. The plot 500 may include an x-axis 510 corresponding to frequency and a y-axis 520 corresponding to the transmission. The plot 500 provides a view of the passband 452. In that regard, the notch 544 may correspond to notch 444 and the notch 546 may correspond to the notch 446. An ideal transmission curve 530 may correspond to the ideal return loss 430 of FIG. 4 and the actual transmission curve 540 may correspond to the actual return loss 440 of FIG. 4.

As shown in FIG. 5, within the band 452, the actual transmission at the notch 544 is within a range of about −3 dB to about −4 dB, while the ideal transmission at the notch 544 is within a range of about −1.5 dB to about −2 dB. At the notch 546, the transmission is within a range of about −2 dB to about −3 dB, while the ideal transmission at the notch 546 is within a range of about −1.5 dB to about −2 dB.

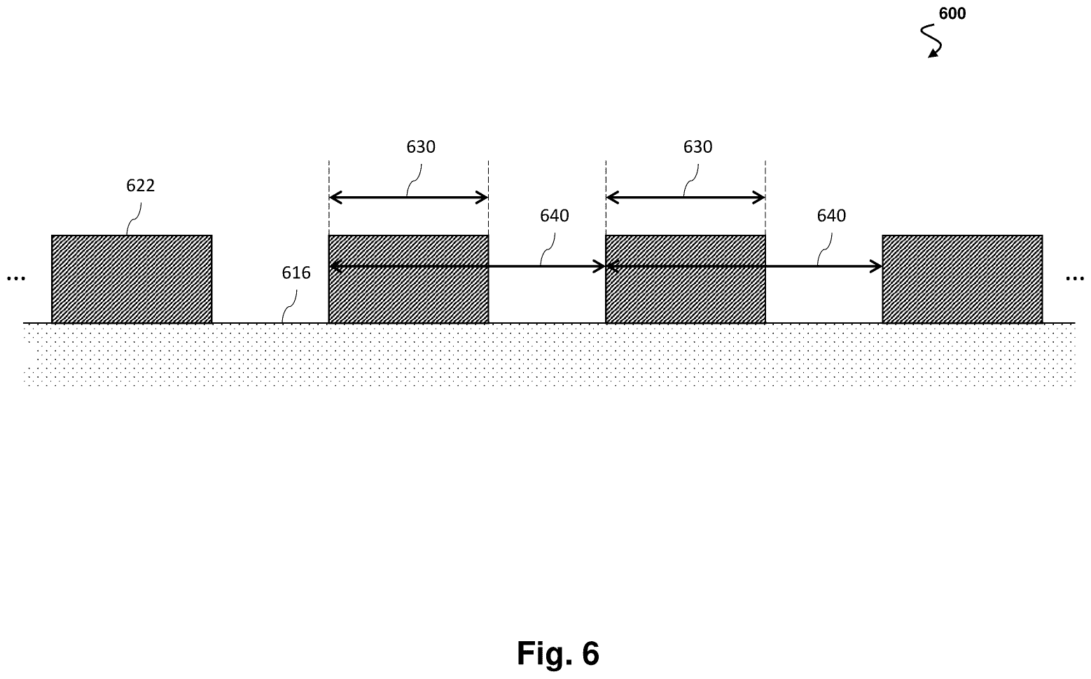

FIG. 6 is a cross-sectional side view of electrodes 622 of an interdigital transducer of a SAW device 600. The SAW device may be similar to any of the SAW devices previously described including the LRT-SAW device 10A of FIG. 1A and/or the TC-SAW device 10B of FIG. 1B, as well as any of the filters shown and described with reference to FIGS. 2 and/or 3. As shown in FIG. 6, the SAW device 600 may include a substrate 616. The substrate 616 may be substantially similar to any of the substrates previously shown and described with reference to FIGS. 1A and/or 1B. In some aspects, the substrate 616 may additionally include a layer disposed over the top of the substrate 616 and between the substrate 616 and the electrodes 622.

FIG. 6 depicts four electrodes 622. However, it is understood that the SAW device 600 may include any suitable number of electrodes and that the figure is only for illustration and that the electrode widths and thicknesses are not scaled equally. In some aspects, the electrodes 622 may be connected to either of two busbars of interdigital transducers. For example, referring to the LRT-SAW device 10A of FIG. 1A, the device 10A includes two busbars connected to an array of multiple electrodes, the busbar 20A and the busbar 20B. Referring again to FIG. 6, similarly, electrodes 622 connected to two similar busbars may be interleaved with another by a one-to-one ratio. It is understood that FIG. 6 may be a simplified representation. While the electrodes are represented as rectangular, they may be shaped according to any suitable shape. Also, the electrodes may each comprise more than one metallic layer to make the fabrication easier or to increase device power handling capability.

In FIG. 6, the electrodes 622 may be spaced according to a pitch 640, as shown. As described with reference to FIG. 1, the pitch between electrodes is the distance between the same or corresponding edges of adjacent electrodes. The electrodes 622 of FIG. 6 may be configured with a width 630.

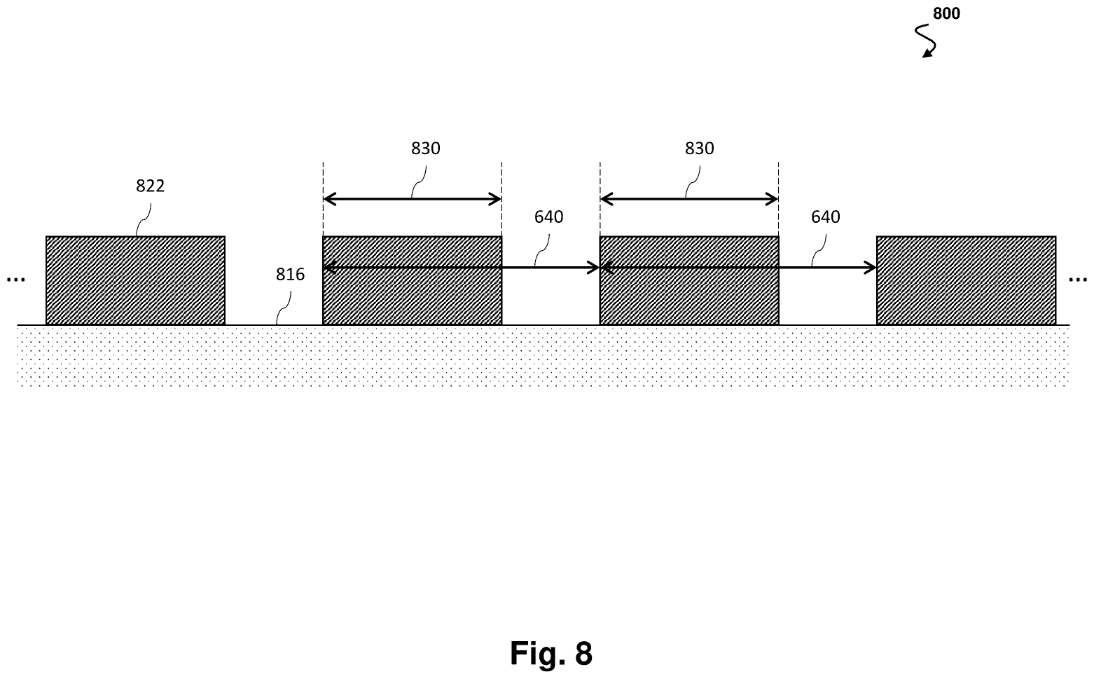

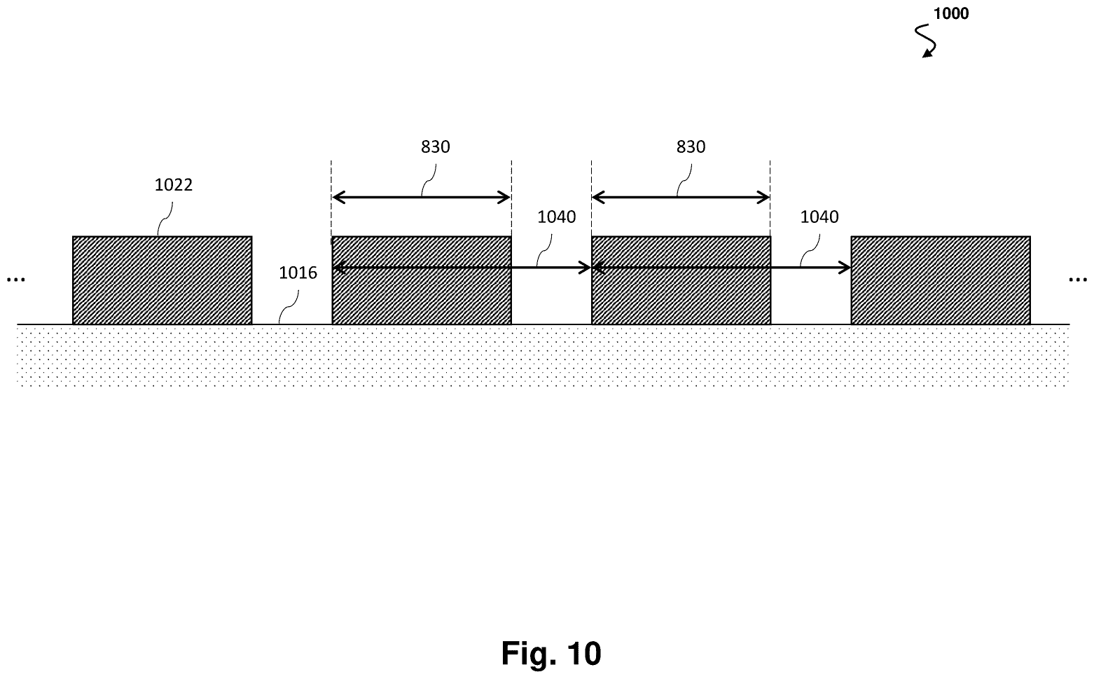

As described with reference to FIG. 1B, the electrodes of a SAW device, such as a TC-SAW device may be embedded in a layer, such as the layer 24. This layer may be constructed of silicon oxide (SiO2) or any other suitable material. Similarly, any of the electrodes of FIGS. 8, 10, and/or 12 may be similarly embedded.

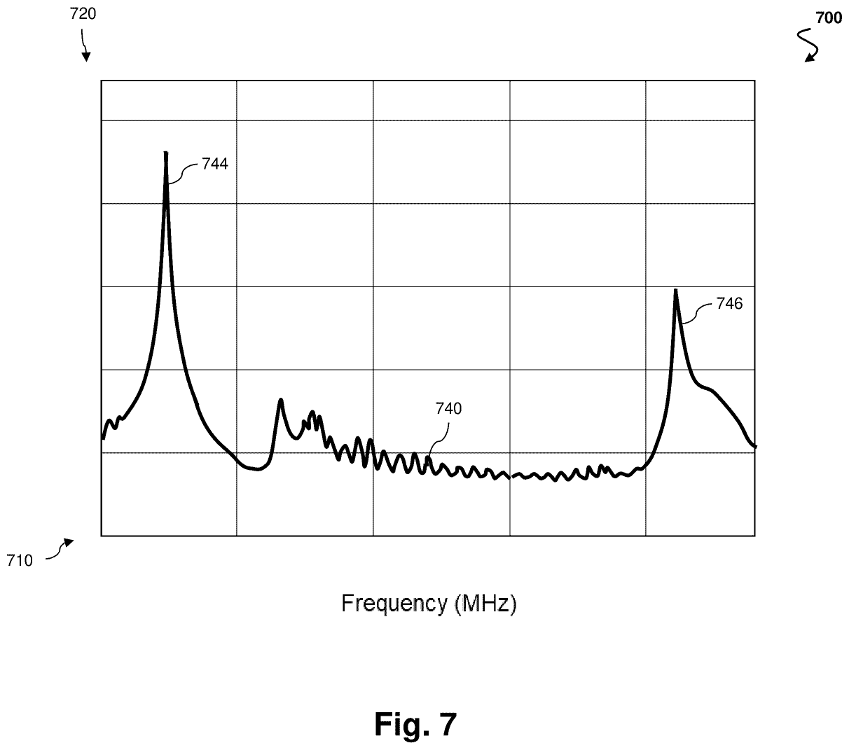

FIG. 7 is a graphical representation of conductance of the SAW device 600. FIG. 7 includes a plot 700. The plot 700 includes an x-axis 710 corresponding to frequency and a y-axis 720 corresponding to a conductance level in units of dB or any other suitable units. The dataset 740 within the plot 700 corresponds to the conductance of the SAW device 600. As shown, the SAW device 600, with a uniform pitch 640 and a uniform width 630, may correspond to a peak 744 corresponding to a fundamental resonant frequency of the SAW device 600. This peak 744 may be configured to be close to the intended pass band of the SAW device 600. However, the dataset 740 also reveals an additional peak 746. While this peak 746 may be sufficiently spaced from the pass band of the device 600 so as not to interfere with signals within that pass band, it may interfere with pass bands of other SAW resonators within a multiplexer circuit or other filters causing degradation of signal quality.

FIG. 8 is a cross-sectional side view of electrodes 822 of a SAW device 800. The SAW device 800 may be similar to any of the SAW devices previously described including the LRT-SAW device 10A of FIG. 1A and/or the TC-SAW device 10B of FIG. 1B, as well as any of the filters shown and described with reference to FIGS. 2, 3, and/or 6. As shown in FIG. 8, the SAW device 800 may include a substrate 816. The substrate 816 may be substantially similar to the substrates previously described. In some aspects, the substrate 816 may additionally include a layer disposed over the top of the substrate 816 and between the substrate 816 and the electrodes 822.

In FIG. 8, the electrodes 822 may be spaced according to the pitch 640, as shown. In that regard, the electrodes 822 may be spaced apart from one another by the same distance as the electrodes 622 of the SAW device 600. However, the device 800 may differ from the device 600 in that the electrodes 822 of FIG. 8 may be configured with a width 830. The width 830 may be greater than the width 630.

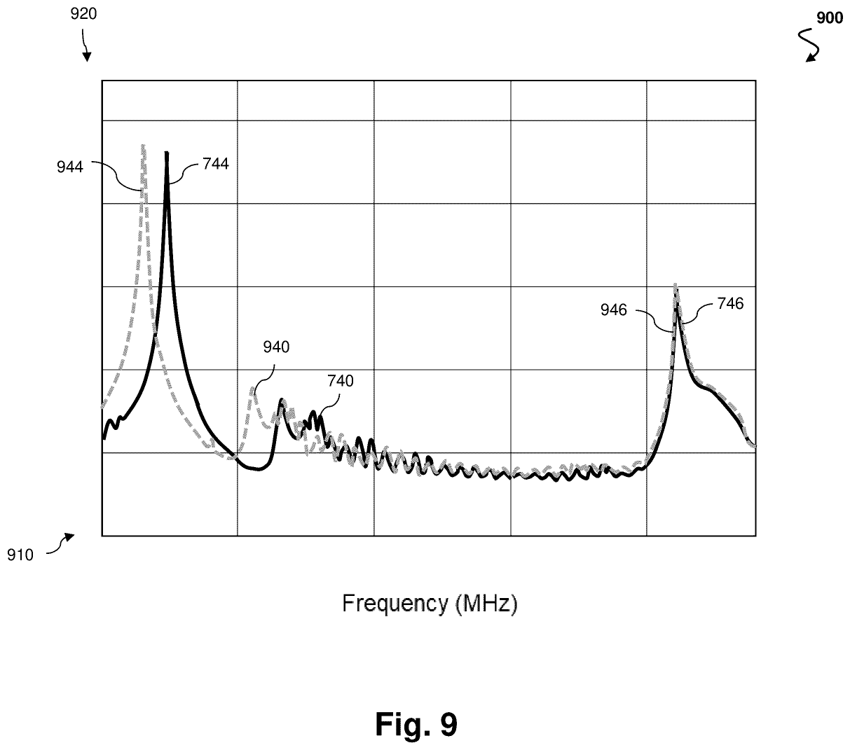

FIG. 9 is a graphical representation of conductance of the SAW device 800. FIG. 9 includes a plot 900. The plot 900 includes an x-axis 910 corresponding to frequency and a y-axis 920 corresponding to a conductance level in units of dB or any other suitable units. The dataset 940 within the plot 900 corresponds to the conductance of the SAW device 800. The plot 900 also includes the dataset 740, the conductance of the SAW device 600 for comparison. As shown, due to the increased width of the electrodes 822 of the SAW device 800, the dataset 940 illustrates a peak 944 corresponding to a fundamental resonant frequency of the SAW device 800 which is lower in frequency than the peak 744. In that regard, the increased width of the IDTs may cause the fundamental resonant frequency of the device to shift lower. The dataset 940 also includes an additional peak 946. As shown in the plot 900, the peak 946, corresponding to a spurious resonant frequency of the device 800, may be unchanged from the peak 746. In that regard, increasing the width of the electrodes 822 may adjust the fundamental frequency lower along the frequency spectrum while leaving the plate mode unchanged.

FIG. 10 is a cross-sectional side view of electrodes 1022 of a SAW device 1000. The SAW device 1000 may be similar to any of the SAW devices previously described including the SAW device 10 of FIG. 1, as well as any of the filters shown and described with reference to FIGS. 2, 3, 6, and/or 8. As shown in FIG. 10, the SAW device 1000 may include a substrate 1016. The substrate 1016 may be substantially similar to the substrate 12 shown and described with reference to FIG. 1 and/or the substrates 616 and/or 816 shown and described with reference to FIGS. 6 and 8 respectively. In some aspects, the substrate 816 may additionally include a layer disposed over the top of the substrate 1016 and between the substrate 1016 and the electrodes 1022.

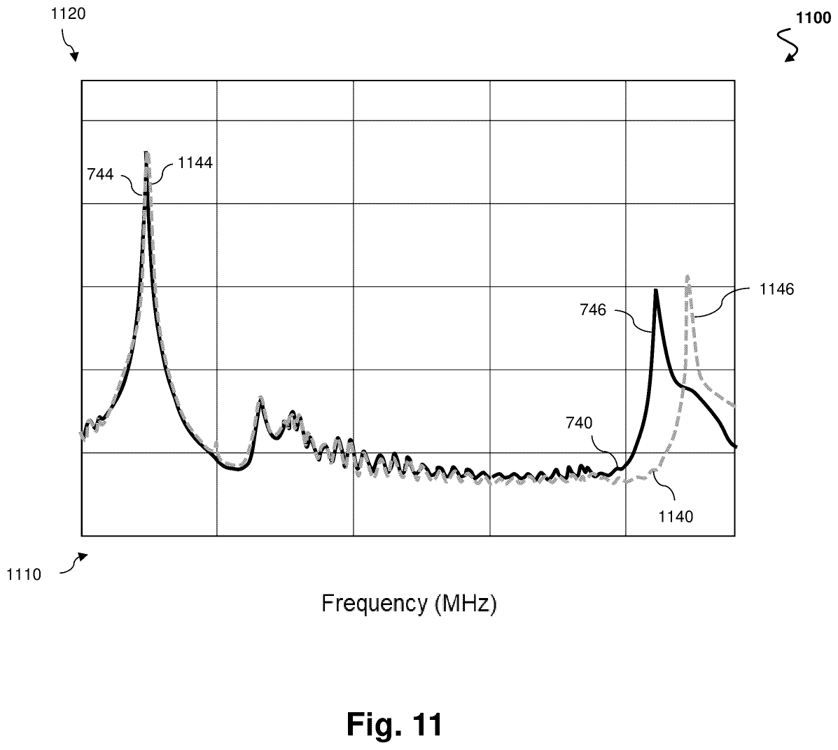

In FIG. 10, the electrodes 1022 may be spaced according to the pitch 1040, as shown. In some aspect, the pitch 1040 may be less than the pitch 640 described with reference to FIGS. 6 and 8. The electrodes 1022 may be of the width 830. In this way, the electrodes 1022 may be of the same width as the electrodes 822 shown and described with reference to FIG. 8. In some aspects, decreasing the pitch of the electrodes 1022 relative to the electrodes 622 and/or 822 may shift the fundamental resonant frequency upwards as shown and described in more detail with reference to FIG. 11.

FIG. 11 is a graphical representation of conductance of a SAW device 1000. FIG. 11 includes a plot 1100. The plot 1100 includes an x-axis 1110 corresponding to frequency and a y-axis 1120 corresponding to a conductance level in units of dB or any other suitable units. The dataset 1140 within the plot 1100 corresponds to the conductance of the SAW device 1000. The plot 1100 also includes the dataset 740, the conductance of the SAW device 600, for comparison. As explained with reference to FIGS. 8-9, as the width of electrodes within a SAW resonator is increased, the fundamental resonant frequency may be decreased without affecting higher order modes. In contrast, decreasing the pitch between electrodes within a SAW resonator increases both the fundamental resonance frequency as well as higher order modes. As a result, and as shown in FIG. 11, although the device 1000 includes electrodes 1022 of increased width 830 (causing the fundamental frequency to shift downwards), this decrease in fundamental frequency is compensated for by decreasing the pitch between the electrodes 1022 such that the fundamental frequency of the device 1000 may be the same as the fundamental frequency of the device 600 as shown by the peaks 744 and 1144 being aligned. In addition, because adjusting the width of the electrodes of a SAW resonator does not affect higher order modes but adjusting the pitch does, by increasing the electrode width to the width 830 (not affecting the higher order resonant frequencies) while simultaneously decreasing the pitch to the pitch 1040 (increasing the higher order resonant frequencies), the peak 1146 corresponding to the higher order resonance frequency or plate mode is shifted higher relative to the peak 746.

In some aspects, simultaneously adjusting the pitch and width of electrodes in a SAW resonator filter such that the fundamental resonance frequency remains essentially the same, but the higher order resonant frequency is shifted upward or downward may provide the advantage of shifting the higher order resonant frequency partially outside of a pass band of another filter of a multiplexer thus increasing the signal quality of other channels. As shown below, an IDT can be divided into individual IDT sections and pitch and width of electrodes belonging to each IDT section may also be varied such that higher order resonant frequencies are shifted by different amounts, reducing the overall amplitude of higher order modes leading to suppressing plate mode and improving signal quality of other bands.

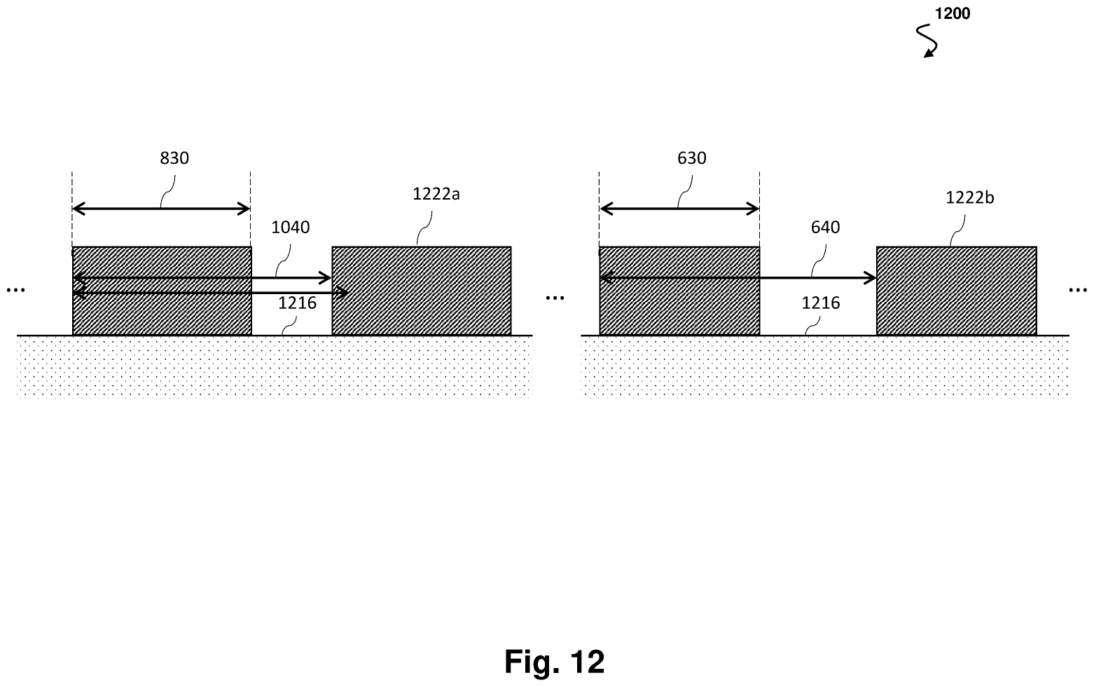

FIG. 12 is a cross-sectional side view of electrodes of a SAW device 1200, according to aspects of the present disclosure. The SAW device 1200 may be similar to any of the SAW devices previously described including the SAW device 10 of FIG. 1, as well as any of the filters shown and described with reference to FIGS. 2, 3, 6, 8, and/or 10. As shown in FIG. 12, the SAW device 1200 may include a substrate 1216. The substrate 1216 may be substantially similar to the substrate 12 shown and described with reference to FIG. 1 and/or the substrates 616, 816, and/or 1016 shown and described with reference to FIGS. 6, 8, and 10 respectively. In some aspects, the substrate 1216 may additionally include a layer disposed over the top of the substrate 1216 and between the substrate 1216 and the electrodes 1222.

FIG. 12 may depict different regions of the same device 1200. For example, on the left, FIG. 12 illustrates two electrodes 1222a that may belong to a specific IDT section. On the right, FIG. 12 illustrates two electrodes 1222b belonging to another IDT section. The region on the left including electrodes 1222a may be a portion of the device 1200 at the edge of the device, for example, near reflectors of a SAW resonator (see e.g., reflectors 18A and/or 18B in FIG. 1). The region on the right including electrodes 1222b may be a portion of the device 1200 towards the middle of a SAW resonator. In other aspects, the electrodes 1222a and 1222b may correspond to any other suitable location within a SAW resonator.

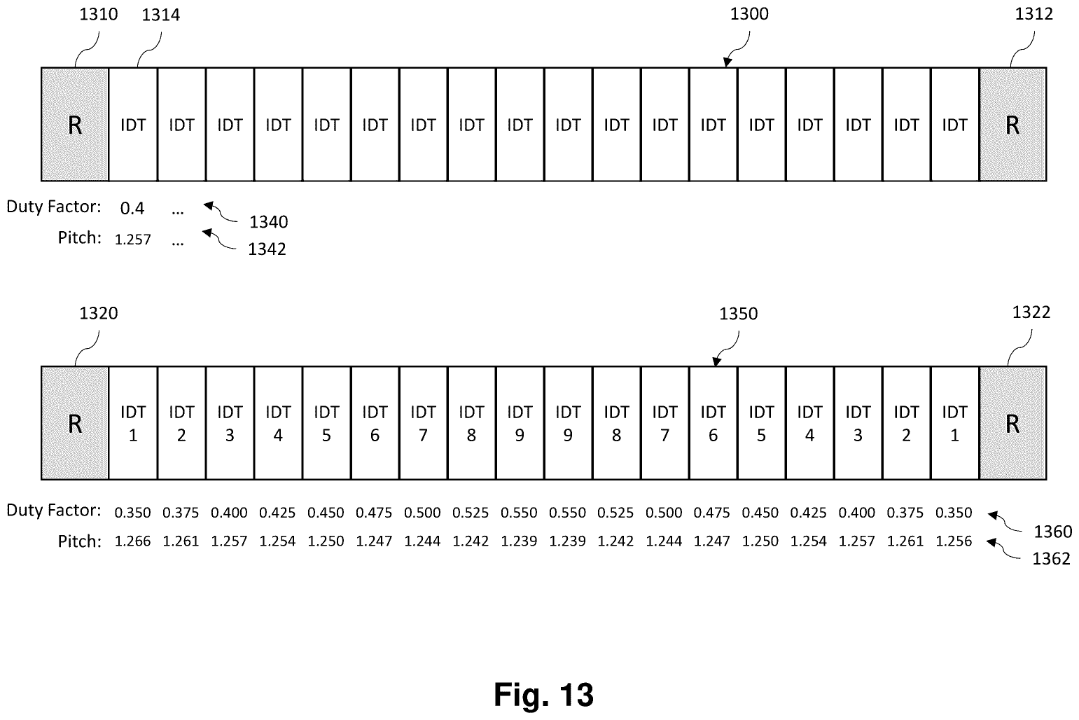

As shown in FIG. 12, the electrodes 1222a of the region on the left may be configured with the width 830 and the pitch 1040. In that regard, the electrodes 1222a may be sized, shaped, and positioned like the electrodes 1022 of the device 1000. Therefore, the conductance of the IDT section including electrodes 1222a may be substantially similar to the dataset 1140 shown in FIG. 11. The electrodes 1222b of the region on the right may be configured with the width 630 and the pitch 640. In that regard, the IDT section including electrodes 1222b may be sized, shaped, and positioned like the electrodes 622 of the device 600. Therefore, the conductance of the IDT section including electrodes 1222b may be substantially similar to the dataset 740 shown in FIG. 7 and FIG. 11. As a result, the IDT section including electrodes 1222a in the left region as well as the IDT section including electrodes 1222b in the right region may all correspond to the same fundamental resonant frequency, as shown by the peaks 744 and 1144 in FIG. 11. However, the IDT section including electrodes 1222a of the left region may have a higher order resonant frequency (e.g., a plate mode) corresponding to the peak 1146 and the IDT section including electrodes 1222b of the right region may have a higher order resonant frequency corresponding to the peak 746. However, by having IDT sections of different widths and pitches in this manner, the overall amplitude of the peaks of the higher order resonant frequencies may be reduced because there are fewer total electrodes corresponding to each higher order resonant frequency. As explained with reference to FIG. 13 hereafter, additional IDT sections may be included within a SAW resonator with slightly varying pitches and widths such that all IDT sections correspond to the same fundamental resonance frequency, but higher order plate mode resonant frequencies are continuously distributed, or spread out, between, for example, the peaks 746 and 1146 shown in FIG. 11. It is also noted that the device 1200 of FIG. 12 may include any suitable number of electrodes 1222a at any suitable position on the SAW resonator as well as any suitable number of electrodes 1222b at any suitable position on the SAW resonator.

FIG. 13 is a diagrammatic view of a SAW device 1300 and a SAW device 1350, according to aspects of the present disclosure. The SAW device 1300 may include a reflector 1310 and a reflector 1312 on opposite ends of the device. A group of IDT sections 1314 each including multiple electrodes may be positioned adjacent to one another between the reflectors 1310 and 1312. In that regard, the device 1300 may be similar to the device 10 shown in FIG. 1.

As shown in FIG. 13, the duty factor 1340 and pitch 1342 may be same for each IDT section 1314. For example, the duty factor 1340 may be 0.4 for each IDT section 1314 within the device 1300. The pitch 1342 may be about 1.257 μm for each IDT section 1314 within the device 1300. Because the duty factor and pitch are uniform for each IDT section 1314 within the device 1300, the conductance of the device may be similar to the conductance of the device 600 shown and described in FIG. 7. In particular, each IDT section 1314 may correspond to the same fundamental resonant frequency and the same plate mode frequency.

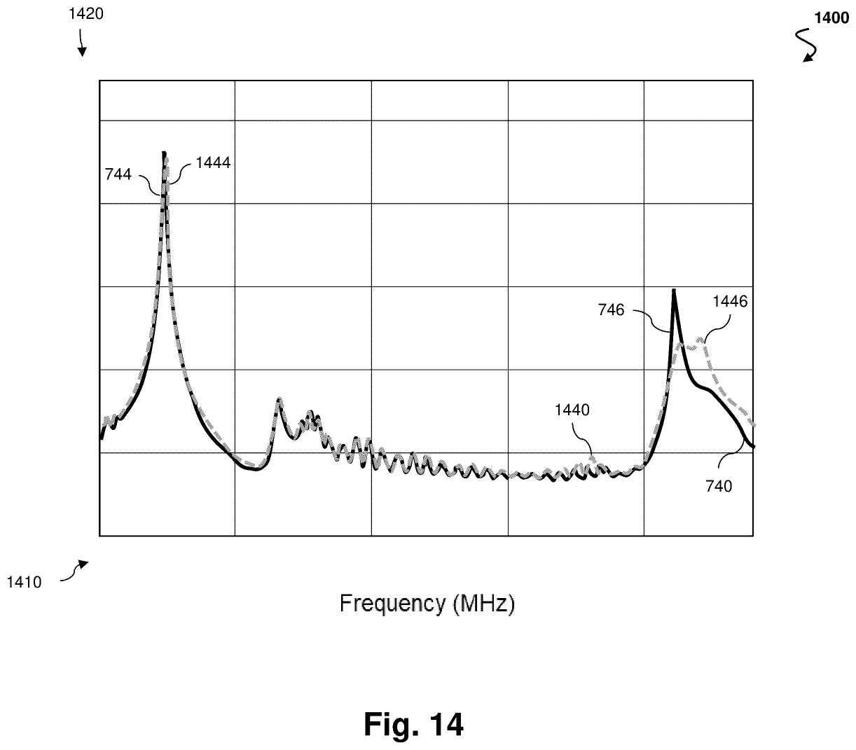

In contrast, device 1350 shows a reflector 1320 and a reflector 1322 with a group of IDT sections in between, wherein the duty factor and pitch of electrodes belonging to each IDT section of the device 1350 are varied. Specifically, the duty factor 1360 of each IDT section within the device 1350 is shown beneath each IDT section. Similarly, the pitch 1362 of each IDT section within the device 1350 is shown. In the example shown, an IDT section 1 is positioned adjacent to each reflector at the ends of group of IDT sections. IDT section 1 has a duty factor of about 0.350 and a pitch of about 1.266 μm. An IDT section 2 is positioned adjacent to each IDT section 1 moving toward the center of the device 1350. IDT section 2 has a duty factor of 0.375 and a pitch of about 1.261 μm. FIG. 13 illustrates how, as the IDT sections progress from IDT section 1 at the edges of the device 1350 to IDT section 9 at the center of the device 1350, the duty factor is gradually increased and the pitch is gradually decreased. The duty factor and pitch may be selected for each IDT section of the device 1350 such that all of the IDT sections 1-9 exhibit the same fundamental resonant frequency. However, the IDT sections 1-9 may be configured such that the higher order plate modes are different and spaced out. Because, in the example shown, only two IDT sections in the group of IDT sections 1-9 correspond to the same parameters and the same higher order resonant frequency, the amplitude of the differentiated higher order resonant frequencies is less than the peak amplitude of the higher order frequency of the device 1300. This is illustrated in FIG. 14 described below. This device may be built on a substrate of lithium niobate of orientation close to Y+127 degrees with a silicon oxide overlay on the electrodes to reduce temperature sensitivity of the design. Typically, the silicon oxide thickness may be larger than about 40% or about 50% of the electrode period. It may be smaller than about 60% of the period. (For the example of FIG. 13, the oxide thickness is about 0.66 μm which is about 52% of the period).

FIG. 14 is a graphical representation of conductance of a SAW device, according to aspects of the present disclosure. In some aspects, the plot 1400 in FIG. 14 depicts the conductance of the SAW device 1350 device or any similar device with IDT sections of varying pitch and duty factor. The plot 1400 includes an x-axis 1410 corresponding to frequency and a y-axis 1420 corresponding to a conductance level in units of dB or any other suitable units. The dataset 1440 within the plot 1400 may correspond to the conductance of the SAW device 1350. The plot 1400 also includes the dataset 740, the conductance of the SAW device 600, for comparison. As explained with reference to FIG. 13, width and the pitch of individual IDT sections within a SAW resonator, such as the device 1350, may be different. As a result, while the fundamental frequency of the IDT sections 1-9 (FIG. 13) may be the same and shown by the peak 1444, which is substantially the same as the peak 744, the higher order resonant frequency of different IDT sections may be different. As a result, the peak 1446 is spread out over a wider range as shown in FIG. 14, with an overall decreased amplitude.

As described previously, adjusting the pitch and duty factor of the IDTs such that the fundamental frequency remains essentially the same and is within the desired pass band of a duplexer or multiplexer while adjusting the resonant frequency of higher order modes may advantageously shift higher order plate mode resonant frequencies outside of pass bands of other filters within multiplexer. However, a SAW resonator with multiple IDT sections of different widths and pitches also advantageously reduces the overall amplitude of higher order modes further improving signal quality.

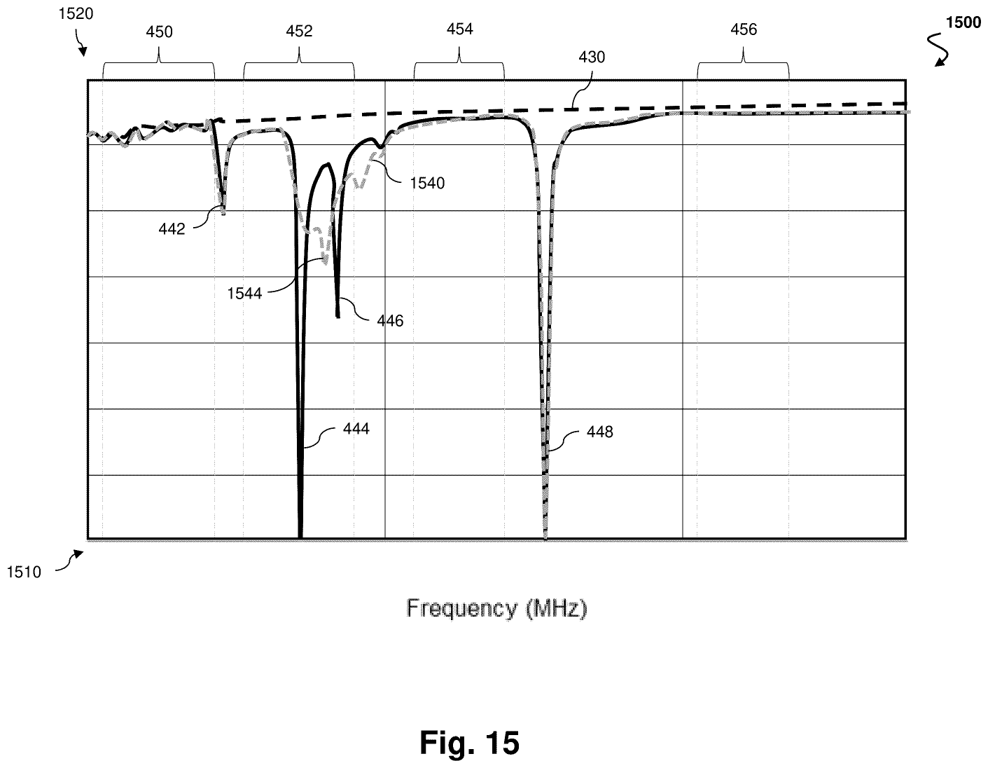

FIG. 15 is a graphical representation of return loss seen from antenna port of a duplexer, according to aspects of the present disclosure. FIG. 15 provides a plot 1500. In some aspects, the plot 1500 may provide a comparison of the return loss seen from antenna port of a duplexer using one or more SAW resonators with IDT sections of varying dimensions such as the device 1350 described previously with the return loss 440 of FIG. 4. In that regard, as described with reference to FIG. 4, the return loss 440 may include multiple notches within passbands of other filters of multiplexer, leading to degraded signal quality. As the plot 1500 includes an x-axis 1510 corresponding to frequency and a y-axis 1520 corresponding to return loss in dB. As shown with trace 1540 corresponding to device 1350 in FIG. 13, the return loss within the band 452 is significantly improved. In particular, while the notch 444 is over about 6 dB below the ideal return loss 430, the return loss 1540 is only about 1 to about 2 dB below the ideal return loss 430 at the same frequency. In addition, the most significant notch 1544 is significantly improved over the notch 444.

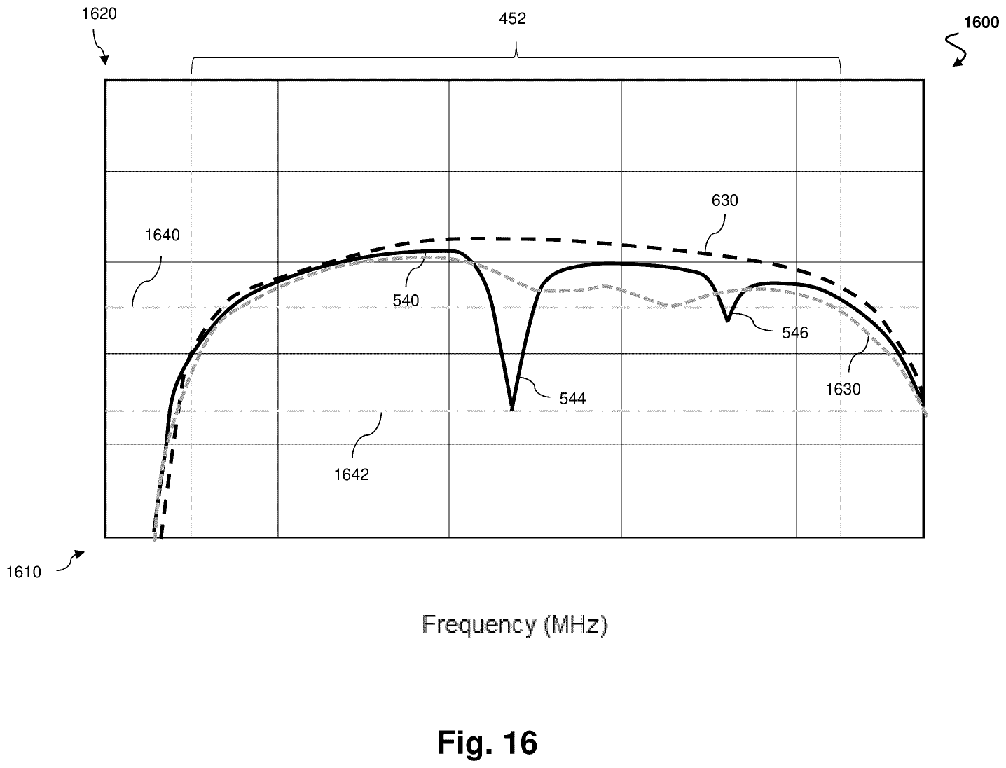

FIG. 16 is a graphical representation of a transmission transfer function of filter in a multiplexer, according to aspects of the present disclosure. FIG. 16 includes a plot 1600. The plot 1600 have an x-axis 1610 corresponding to frequency and a y-axis 1620 corresponding to transmission response of the filter. The plot 1600 provides a view of the passband 452. The transmission 540 is shown including notches 544 and 546. Transmission 1630 is also shown for comparison. Transmission 1630 may be the transmission of the filter when multiple IDT sections of different pitch and duty factor are included within SAW resonators of the device.

As shown in FIG. 16, within the band 452, the actual transmission 1630 is significantly improved. In particular, a line 1642 is included within the plot 1600 identifying the minimum value of the transmission 540 within the band 452. As shown, the line 1642 in FIG. 16 corresponds to about −3.7 dB. By contrast, a line 1640 is included within the plot 1600 identifying the minimum value of the transmission 1630. As shown the line 1640 correspond to about −2.5 dB.

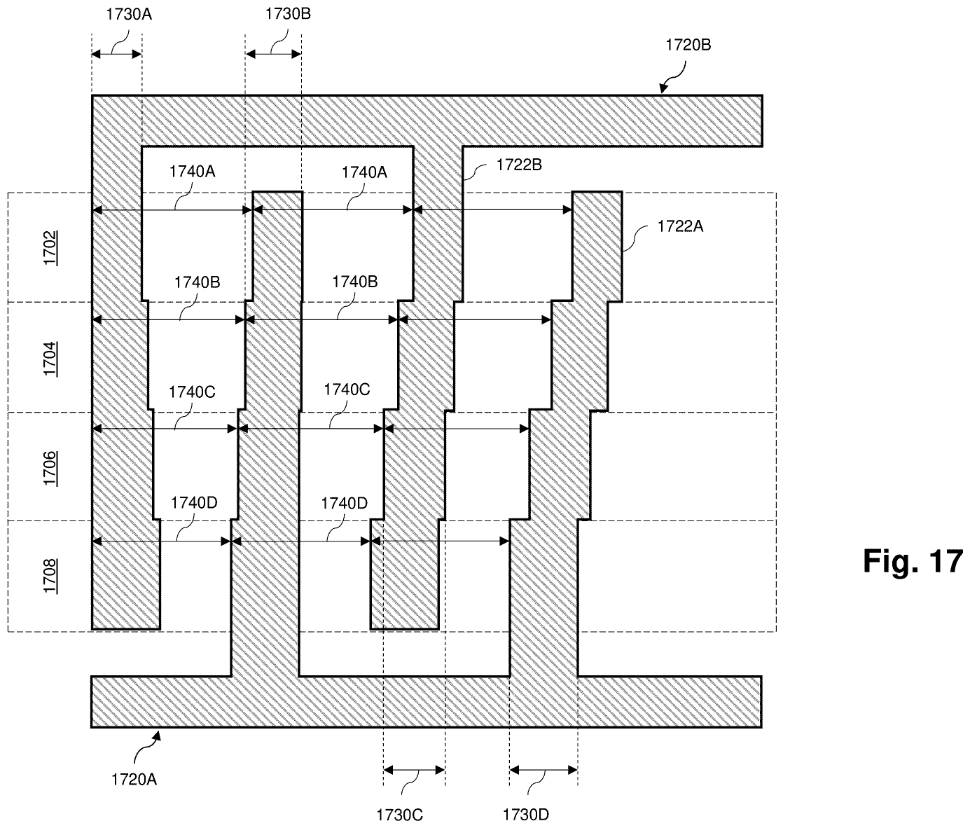

FIG. 17 is a top view of electrodes 1722 of a SAW resonator, according to aspects of the present disclosure. FIG. 17 depicts a busbar 1720B connected to electrodes 1722B and a busbar 1720A connected to electrodes 1722A. The IDT formed from electrodes 1722 may differ from the devices previously described. For example, while the electrodes of the device 1350 may be of different widths and arranged according to different pitches as described with reference to FIG. 13, the electrodes of the device 1350 are of a constant width along the length of each electrode. By contrast, and as shown in FIG. 17, the electrodes 1722 are not of constant width. In that regard, the width and pitch along each electrode is varied.

In the non-limiting example shown in FIG. 17, four regions may extend horizontally across the electrodes 1722A. These regions include region 1702, 1704, 1706, and 1708. Each electrode 1722 extends through each of these regions and is positioned substantially perpendicular to the length of the regions, as shown. The regions 1702, 1704, 1706, and 1708 show four different sections of each electrode 1722. Specifically, the sections of the electrodes 1722 corresponding to the region 1702 may be of the same the width 1730A and the same pitch 1740A. In that regard, the proximal end of each electrode 1722B of the busbar 1720B may be of the width 1730A. Similarly, the distal end of each electrode 1722A of the busbar 1720A may be of the same width 1730A. The sections of the electrodes 1722 corresponding to the region 1704 may be of the same the width 1730B and the same pitch 1740B. The sections of the electrodes 1722 corresponding to the region 1706 may be of the same the width 1730C and the same pitch 1740C. The sections of the electrodes 1722 corresponding to the region 1708 may be of the same the width 1730D and the same pitch 1740D.

In that regard, the width and pitch of the electrodes 1722 within each region 1702, 1704, 1706, and 1708 may be selected to correspond to the same fundamental resonant frequency. However, the higher order plate modes of the different regions of the electrodes 1722 may be different thus producing a conductance of the SAW resonator similar to that shown by the dataset 1446 of FIG. 14.

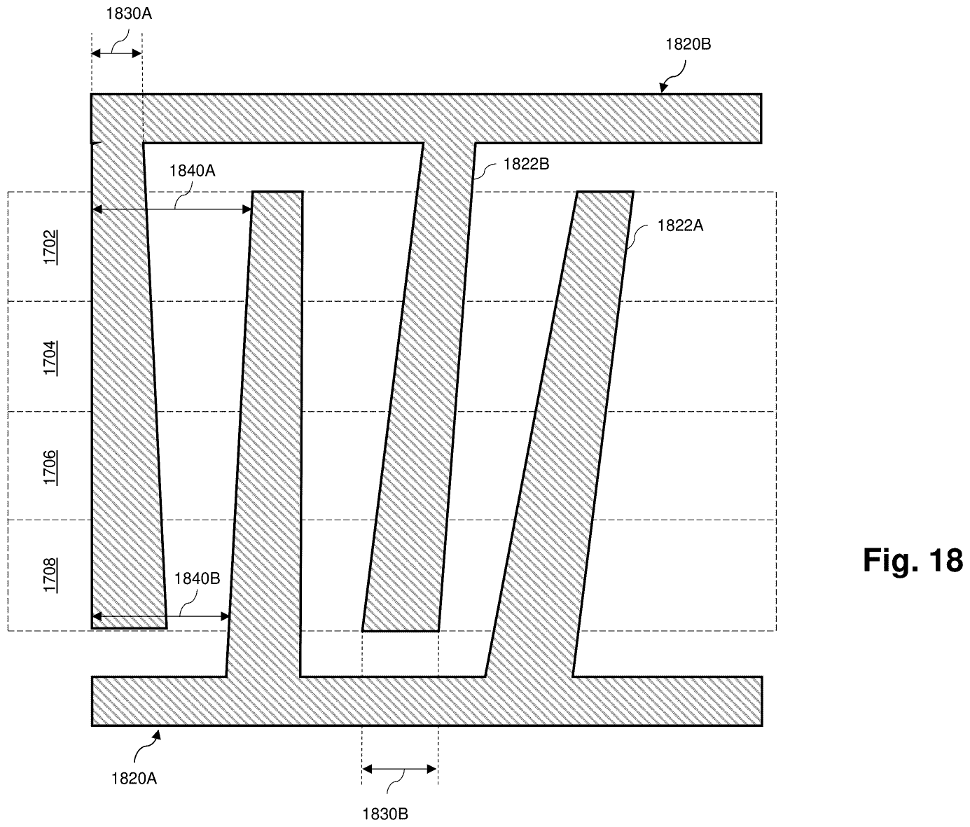

FIG. 18 is a top view of electrodes 1822 of IDT of a SAW resonator, according to aspects of the present disclosure.

The size, shape, and position of the electrodes 1822 shown in FIG. 18 may function similarly to the electrodes 1722 shown and described in FIG. 17. In particular, the width and pitch of the electrodes 1822 may be varied along the length of each electrode 1822. For example, at one end of each electrode (a proximal end of the electrodes 1822B and a distal end of the electrodes 1822A), the width of the electrodes 1822 may be 1830A and the pitch may be 1840A as shown in FIG. 18. At the opposite end of the electrodes 1822 (a distal end of the electrodes 1822B and a proximal end of the electrodes 1822A), the width of the electrodes 1822 may be 1830B and the pitch may be 1840B. The width and pitch of the electrodes 1822 may be continuously varied between these two points creating a gradual change along each electrodes 1822. In that regard, at every point along each electrode 1822, the fundamental resonant frequency is the same. However, the higher order resonant frequency, such as the plate mode of the electrodes is varied with length along each electrode 1822. In a more complex configuration, resonator may use variation of pitch and duty factor both in its length as seen on FIG. 13 and its aperture as seen on FIGS. 17 and 18.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

What is claimed is:

1. A surface acoustic wave (SAW) resonator device, comprising:
a piezoelectric layer;
a first subset of electrodes positioned on the piezoelectric layer, the first subset of electrodes corresponding to:
a first width;
a first pitch;
a fundamental resonant frequency; and
a first higher order resonant frequency; and
a second subset of electrodes positioned on the piezoelectric layer, the second subset of electrodes corresponding to:
a second width;
a second pitch;
the fundamental resonance frequency; and
a second higher order resonant frequency different from the first higher order resonant frequency.

2. The SAW resonator device of claim 1, wherein the first width is greater than the second width and wherein the first pitch is less than the second pitch.

3. The SAW resonator device of claim 1, wherein each electrode of the first and second subsets of electrodes comprises an upper electrode layer and a lower electrode layer.

4. The SAW resonator device of claim 1, wherein the first higher order resonant frequency and the second higher order resonant frequency corresponding to a peak that is lower in amplitude than a corresponding number of electrodes of uniform width and uniform pitch.

5. The SAW resonator device of claim 1, further comprising a third subset of electrodes positioned on the piezoelectric layer, the third subset of electrodes corresponding to:
a third width;
a third pitch;
the fundamental resonance frequency; and
a third higher order resonant frequency different from the first higher order resonant frequency and the second higher order resonant frequency.

6. The SAW resonator device of claim 1, wherein:
the electrode periods and the electrode widths vary along the resonator; and
a larger electrode width correspond to a smaller pitch.

7. The SAW resonator device of claim 1, wherein either of the first higher order resonant frequency or the second higher order resonant frequency corresponds to a plate mode.

8. The SAW resonator device of claim 1, wherein the electrodes of the first and second subsets of electrodes are embedded in a dielectric material.

9. The SAW resonator device of claim 7, wherein the dielectric material is silicon oxide.

10. The SAW resonator of claim 9, wherein the dielectric material thickness is greater than about 30% of the period.

11. The SAW resonator of claim 9, wherein the piezoelectric material includes lithium niobate with an orientation between about Y+115 deg. and about Y+130 deg.

12. The SAW resonator device of claim 1, wherein the piezoelectric layer is lithium tantalate or lithium niobate.

13. A multiplexer system, comprising:
a receive port;
a transmit port;
an antenna port; and
a plurality of filters in communication with the receive port, the transmit port, and the antenna port, wherein a first filter of the plurality of filters includes a surface acoustic wave (SAW) resonator comprising an interdigital transducer including a plurality of electrodes, wherein the interdigital transducer comprises:
a first section with a first electrode width and a first electrode pitch corresponding to a fundamental resonant frequency and a first higher order resonant frequency; and
a second section with a second electrode width and a second electrode pitch corresponding to the fundamental resonance frequency and a second higher order resonant frequency different from the first higher order resonant frequency.

14. The multiplexer system of claim 13, wherein the SAW resonator is directly coupled to the antenna port.

15. The multiplexer system of claim 13, wherein each electrode of the plurality of electrodes comprises a first region of a first width and a first pitch and a second region of a second width and a second pitch.

16. The multiplexer system of claim 15, wherein:
a first subset of electrodes corresponds to a first busbar of the interdigital transducer and wherein the first region of the first subset of electrodes corresponds to a proximal region and the second region of the first subset of electrodes corresponds to a distal region; and
a second subset of electrodes corresponds to a second busbar of the interdigital transducer and wherein the first region of a second subset of electrodes corresponds to a distal region and the second region of the second subset of electrodes corresponds to a proximal region.

17. The multiplexer system of claim 15, wherein the width and pitch of each electrodes of the plurality of electrodes is continuously varied along the length of each electrode between the first region and the second region.

18. The multiplexer system of claim 13, wherein the first section includes a first subset of the plurality of electrodes and the second section includes a second subset of the plurality of electrodes.

19. The multiplexer system of claim 18, wherein the first subset of the plurality of electrodes correspond to the first electrode width and the first electrode pitch.

20. An interdigital transducer (IDT), comprising:
a plurality of sections, wherein each section of plurality of sections corresponds to:
a different period; and
a different electrode width;
wherein the period and electrode of the plurality of sections is varied according to an inverse relationship such that sections of increased electrode width correspond to decreased period.
